(19) United States
(12) Patent Application Publication
(10) Pub. No.: US 2001/0012692 A1
(43) Pub. Date: Aug. 9, 2001

(54) THICK-FILM ETCH-BACK PROCESS FOR USE IN MANUFACTURING FINE-LINE HYBRID CIRCUITS

(76) Inventors: ROBIN L. MILLER, WESTFORD, MA (US); PHUNG DAC NGUYEN, BRADFORD, MA (US)

Correspondence Address: GLEN E. BOOKS, ESQ., LOWENSTEIN SANDLER PC, 65 LIVINGSTON AVENUE, ROSELAND, NJ, 07068, US

(21) Appl. No.: 09/204,405

(22) Filed: Dec. 2, 1998

Related U.S. Application Data
(60) Provisional application No. 60/106,415, filed on Oct. 30, 1998.

(51) Int. Cl. H01L 21/44; H01L 21/302; H01L 21/461

(52) U.S. Cl. 438/669; 438/671; 438/754

(57) ABSTRACT

A method for making thick-film conductor line patterns having conductor linewidths and spacings which are each less than about 5 mils. The method is especially useful in manufacturing fine-line hybrid circuits. The method involves forming a conductor line circuit pattern of thick-film material on a principle surface of a substrate. The principle surface of the substrate is masked so that selected portions of the conductor line circuit pattern are exposed. The exposed portions of the pattern are then removed from the substrate to reduce the conductor linewidths and spacings of the pattern to less than about 5 mils.

This application claims the benefit of U.S. Provisional application no. 60/106,415 entitled THICK-FILM ETCH-BACK PROCESS FOR USE IN MANUFACTURING FINE-LINE HYBRID CIRCUITS filed by applicants on Oct. 30, 1998.

### FIELD OF THE INVENTION

This invention relates to fine-line hybrid circuits, and in particular, to a thick-film photolithographic etch-back process for making thick-film conductor lines having linewidths and spacings less than 5 mils.

### BACKGROUND OF THE INVENTION

A hybrid circuit is a combination of thick or thin-film components, monolithic semiconductor devices, and discrete parts on a common substrate. Hybrid circuits provide high performance and board size reduction in a vast assortment of electronic applications including but not limited to microwave, lightwave satellite communications, signal processing, switching, transmission, wireless, and data communications.

Hybrid circuits are produced by depositing thick-film and/or thin-film metallization patterns on the substrate. These film patterns form conductor lines, crossunders, bonding pads, die pads, inductors, capacitors and resistors. The substrate is laser scribed and snapped to approximately the same width and length as the finished hybrid package. The active and passive components are then bonded to the substrate. The conductor tracks on the substrate interconnect the circuit components and connect the hybrid circuitry to external lead bonding pads.

Thick-film deposition methods utilize inks or pastes which have particles which define the electrical properties of the film. The inks or pastes are screen printed in a predetermined pattern onto the substrate. The pattern is dried and then fired to fuse the particles together adhere the pattern to the substrate. Fired thick-films are typically about 0.5 to 2.0 mils in thickness.

Thin-film deposition methods used in the manufacture of hybrid circuits consist of a series of process steps involving deposition, photolithography, plating, and etching. The films produced by these steps are typically of the order of a few micrometers (μm) in thickness. Some fabrication processes involve plating the conducting metal structures onto the substrate and are thus, termed additive processes. More common thin-film processes coat the entire substrate surface with a conducting metal layer and then remove the unwanted metal from between the conductors and are thus, termed subtractive processes.

Current hybrid circuit designs are using conductor circuit patterns with conductor lines of narrower line-widths to reduce circuit size, power requirements and heat generation. Thick-film deposition methods can produce circuit patterns with conductor line-widths as thin as about 5 mils. However, applications requiring conductor line-widths of less than 5 mils must be produced using thin-film deposition methods.

Unfortunately, thin-film deposition methods are more costly and complicated than thick-film deposition methods because they involve multiple process steps which increase processing time and require chemical waste disposal handling of the etchants and plating solutions.

Another approach for making conductor circuit patterns with conductor line-widths of less than 5 mils involves etchable thick-films. This approach uses a combination of thick and thin-film processing. In etchable thick film, photoimagable dielectric and conductive pastes are used. These pastes have a photosensitive polymer mixed in so that the printed and dried paste can be exposed, with UV light through a photomask, to create features as narrow as 50 microns. A blanket coat of this photoimagable paste is printed across the entire working surface of the substrate, dried and fired. Photoresist is then applied, exposed to ultraviolet light through a desired pattern, and developed to form a negative image. The exposed thick film is then etched using an aqueous solution.

The etchable thick-film method has two significant disadvantages. First, the etchable thick-films must be specially-formulated with photosensitive additives. Second, a substantial amount of material is removed during etching because the entire surface of the substrate is coated with the fired paste. This in turn increases the costs of paste material, metal reclamation, and etchant solution.

Accordingly, there remains a need for a less expensive method for producing conductor line-widths of less than 5 mils.

### SUMMARY

A method for making thick-film conductor line patterns having conductor linewidths and spacings which are each less than about 5 mils. The method comprises forming a conductor line pattern of thick-film material on a principle surface of a substrate. The principle surface of the substrate is masked so that selected portions of the conductor line pattern are exposed. The exposed portions of the conductor line pattern are removed from the substrate to reduce the conductor linewidths and spacings of the pattern to less than about 5 mils.

### BRIEF DESCRIPTION OF THE DRAWINGS

The advantages, nature and various additional features of the invention will appear more fully upon consideration of the illustrative embodiments now to be described in detail in connection with the accompanying drawings wherein:

FIG. 1 is a schematic flow diagram showing the steps of a thick-film photolithographic etch-back method of the present invention;

FIG. 2A is a schematic top view of a conductor line of a typical thick-film conductor line circuit pattern after firing;

FIG. 2B is a schematic top view of the conductor line of FIG. 2A covered by a segment of an etch mask;

FIG. 2C is a schematic top view of the conductor line of FIG. 2A after etching;

FIG. 3 is a top view of a substrate with a typical thick-film conductor line circuit pattern made according to the method of the present invention; and

FIG. 4 is a schematic perspective view of a crossunder thick-film conductor line of a hybrid circuit made according to the method of the present invention.

It is to be understood that these drawings are for purposes of illustrating the concepts of the invention and, except for graphical illustrations, are not to scale.

### DETAILED DESCRIPTION OF THE INVENTION

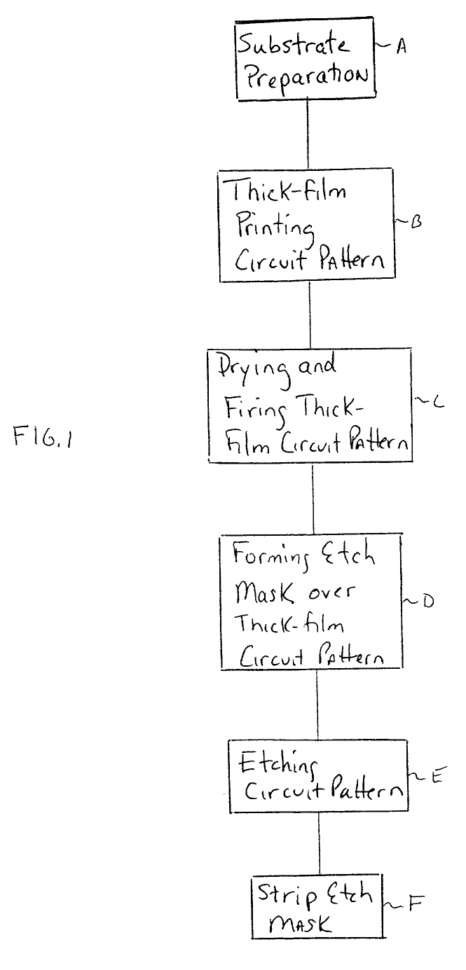

FIG. 1 is a schematic flow diagram showing the steps of a thick-film photolithographic etch-back method of the present invention. The method permits the fabrication of circuits, such as hybrid circuits, with thick-film conductor line resolutions down to about 35 microns. In the first step shown in block A of FIG. 1, a fired substrate is prepared for thick-film printing. The substrate is typically made from an alumina (Al₂O₃) ceramic material having a thermal conductivity of about 0.037 W/mm° C., a dielectric constant of about 10, a coefficient of thermal expansion of about 6.7×10⁻⁶/° C. The substrate can have a thickness of about 0.027 inches.

Substrate preparation is typically accomplished using the following procedure. First, any vias required for circuit grounding or other purposes are fabricated in the fired substrate. This is typically accomplished by laser drilling using either a CO₂ or Nd:YAG laser.

If drilling has been performed, the substrate must be bead blasted to remove any randomly scattered re-solidified ceramic material (slag) absorbed on the surfaces of the substrate during laser drilling. Bead blasting also provides the substrate with a second-order peening-stress relieving effect.

After bead blasting, the substrate is ultrasonically cleaned to provide good thick-film adhesion and microstructure integrity. Substrates made from alumina are chemically resistant and can be cleaned in mild or strong aqueous organic solvents and mild aqueous solutions. Alternating acid-alkali processes can also be used for cleaning alumina substrates.

Finally, a low melting silicate glass is applied to a principle surface of the substrate and fired to melt and fuse the glass to the surface. The glass improves the finish of the substrate surface and thus, permits any future thin-film processing.

The next step, shown in block B of FIG. 1, involves thick-film printing a circuit pattern of conductor lines onto the glazed principle surface of the substrate. Printing is accomplished using conventional thick-film screen printing methods and a standard, commercially available thick-film gold conductor material such as Dupont 4147, manufactured and sold by E. I. du Pont Nemours and Company. The conductor lines of the pattern are printed wider than the final required linewidth. For example, to create a 5 mil wide by 100 mil long conductor feature, the pattern in the screen can be enlarged to 9 mils by 104 mils. The material to be etched will define a 2 mil wide border around the feature.

The third step shown in block C of FIG. 1, includes drying and firing the printed conductor line circuit pattern. The substrate is set aside to allow the conductor line circuit pattern to air dry at room temperature for about 10 to 30minutes. Air drying permits leveling of the conductor paste surface. Because the surface area to volume ratio of deposited films is high, drying at about 80 to 160° C. for a period of about 10 to 30 minutes is adequate to remove most of the solvents from the wet print. Drying is completed by placing the substrate in a convection dryer. The thickness of the dried thick-film circuit pattern is periodically measured for process control purposes. The air flow rates inside the dryer and drying temperature also are constantly monitored.

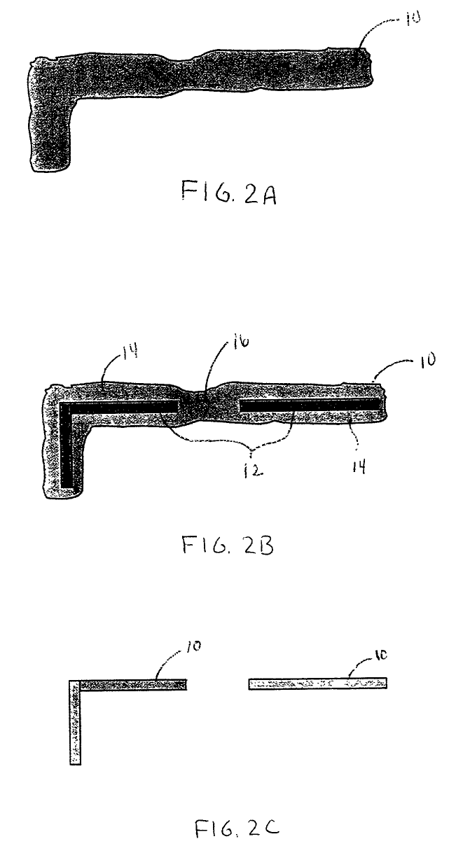

The dried thick-film circuit pattern is then fired in a belt furnace to densify the gold particles in the paste and adhere the pattern to the substrate. Belt furnaces provide easy process automation. Typical belt furnaces have several zones through which a belt travels at a constant speed. The heating elements are wrapped around a metallic muffle, which transfers the heat to the substrate. The zone temperature and the speed of the belt can be controlled independently. By adjusting the zone temperature and the belt speed, a variety of time vs. temperature profiles can be achieved. The typical firing profile for the gold conductor paste has a peak temperature of about 980° C. Cooling is accomplished with a water-cooled jacket that surrounds the belt during the final few feet of belt travel. FIG. 2A shows an “oversized” conductor line 10 of a typical thick-film conductor line circuit pattern after firing.

The fourth step shown in block D of FIG. 1, consists of covering the fired conductor line circuit pattern with a layer of photoresist and patterning it to create an etch mask. The etch mask is substantially similar to the underlying thick-film conductor line circuit pattern however, it has narrower and shorter conductor lines which expose portions of the thick-film pattern. This is illustrated in FIG. 2B which shows the conductor line 10 of FIG. 2A covered by a segment 12 of an etch mask. The etch mask segment 12 essentially follows the underlying thick-film conductor line 10 but, selectively exposes edges 14 and other portions 16 of the conductor line 10.

The photoresist is preferably a positive-type emulsion such as is available from Hoechst Celanese under the part no. AZ4902. The photoresist is conventionally applied by spraying in an automated conveyorized spray booth. In spray coating, a spray gun applies the resist as small droplets, which then coalesce into a continuous coating. Spraying permits good surface coverage over raised conductors. The emulsion is pre-baked to harden it and increase its etch resistance. An image of a master mask (defining the desired conductor line pattern) is reproduced onto the photoresist by exposing sections of the photoresist coated substrate with ultraviolet light. The photoresist is then developed by washing the photoresist with a chemical solution which removes the light-exposed sections of the photoresist and uncovers the underlying unwanted portions of the conductor line pattern. The photoresist is then post baked to remove any developer and further harden it.

The fifth step shown in block E of FIG. 1, involves etching of the exposed portions of the thick-film conductor circuit pattern to reduce its dimensions to a desired conductor linewidth, length and spacing. Etching consists of immersing the substrate into a strong chemical solution which dissolves the unprotected thick-film conductor line pattern portions. The substrate is then rinsed to prevent undercutting of the conductor lines and to remove any residue of the etching solution and etched metal.

In the final step shown in block F of FIG. 1, the etch mask is stripped from the substrate using conventional methods. FIG. 2C shows the conductor line of FIG. 2A after etching.

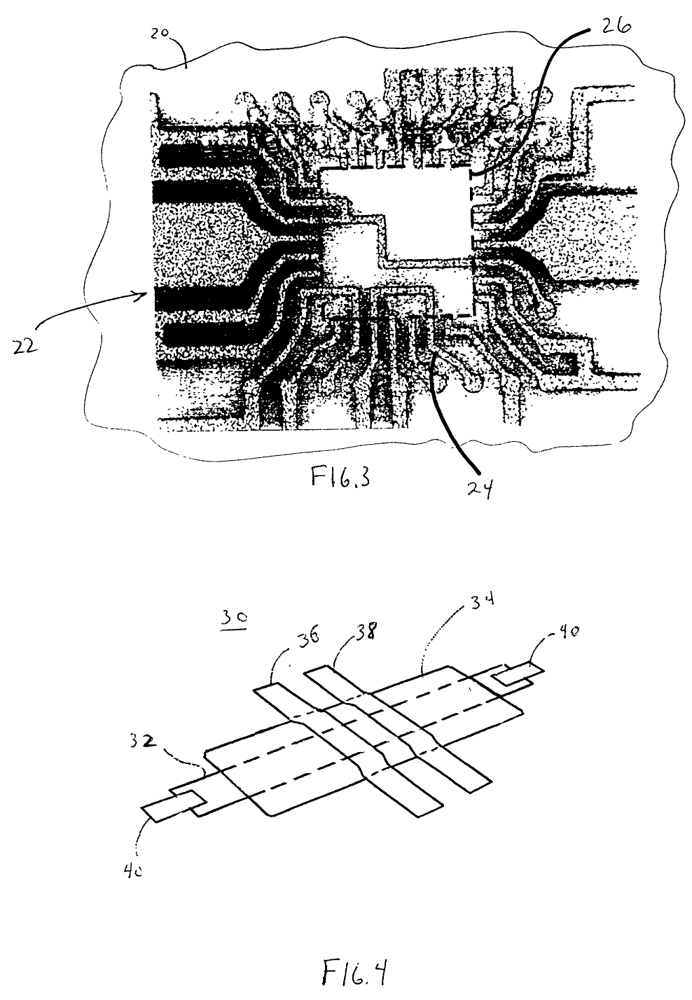

FIG. 3 shows a substrate section 20 of a hybrid circuit with a typical thick-film conductor line circuit pattern 22 made according to the method of the present invention. Such circuit patterns are used for electrically interconnecting hybrid circuit components and electrically connecting the hybrid circuitry to external lead bonding pads. The circuit pattern 22 has conductor lines 24 with linewidths and spacings that are each typically less than 5 mils. A hybrid circuit component 26 (shown with broken lines) is bonded to the substrate section 20.

FIG. 4 shows a crossunder thick-film conductor line 32 of a hybrid circuit 30 made according to the method of the present invention. A dielectric insulator layer 34 (formed by two thick-film glaze layers) covers the thick-film crossunder 32 and two thin-film conductors 36, 38 cross over the thick-film crossunder 32 and thick-film dielectric layer 34. The ends of the thick-film crossunder 32 include thin-film conductor tabs 40.

Circuits having multiple conductor levels with conductor lines fabricated with the thick-film photolithographic etch-back method of the present invention are also possible. The conductor levels of such circuits can be separated by dielectric insulating levels.

The thick-film photolithographic etch-back method of the present invention advantageously permits standard thick film pastes to be used for fabricating thick-film conductors of comparable line density and conductivity to that of thin film when matched with a compatible chemical-etching process. No photosensitive additives are required in the paste. Thick-film conductors having linewidths as narrow as 35 microns can be made using a conductor paste with a large gold particle size not previously considered usable for fine-line printing. Conductor pastes utilizing smaller gold particle sizes which produce denser fired films, can provide even narrower conductor lines when fabricated using the inventive method.

Additionally, the method of the present invention substantially reduces the amount of conductor material that must be etched as compared to conventional processes which require a blanket print of material. By creating an oversized, code-specific, conductor pattern, the amount of paste printed is just slightly more than is required for the final conductor.

While the foregoing invention has been described with reference to the above embodiments, various modifications and changes can be made without departing from the spirit of the present invention. Accordingly, modifications and changes such as those suggested above but not limited thereto are considered to be within the scope of the claims.

What is claimed is:

1. A method for making thick-film conductor line patterns having conductor linewidths and spacings which are each less than about 5 mils, the method comprising the steps of:
forming a conductor line pattern of thick-film material on a principle surface of a substrate;
masking the principle surface of the substrate so that selected portions of the conductor line pattern are exposed; and
removing the exposed portions of the conductor line pattern from the substrate to reduce the conductor linewidths and spacings of the pattern to less than about 5 mils.

2. The method according to claim 1, wherein the conductor linewidths and spacings are each about 35 microns.

3. The method according to claim 1, wherein the conductor line pattern is formed with conductor linewidths and spacings which are each slightly greater than the final desired linewidths and spacings.

4. The method according to claim 1, wherein the forming step comprises the steps of:
printing the conductor line pattern of the thick-film material on the principle surface of the substrate; and
firing the printed conductor line pattern to densify particles in the thick-film material and adhere the pattern to the substrate.

5. The method according to claim 1, wherein the masking step comprises to steps of:
covering the principle surface of the substrate with a layer of photoresist; and
patterning the layer of photoresist so that the selected portions of the underlying conductor line pattern are exposed.

6. The method according to claim 1, wherein the removing step is performed by etching the substrate.

7. The method according to claim 1, wherein the conductor line pattern of the thick-film material comprises a conductor line circuit pattern of a hybrid circuit.

8. A method for making a hybrid circuit, the method comprising the steps of:
forming a conductor line circuit pattern of thick-film material on a principle surface of a substrate;
masking the principle surface of the substrate so that selected portions of the conductor line circuit pattern are exposed;
removing the exposed portions of the conductor line circuit pattern from the substrate to reduce the conductor linewidths and spacings of the pattern to less than about 5 mils;
bonding at least two active devices to the substrate, the conductor line circuit pattern electrically interconnecting the active devices.

9. The method according to claim 8, wherein the conductor linewidths and spacings are each about 35 microns.

10. The method according to claim 8, wherein the conductor line pattern is formed with conductor linewidths and spacings which are slightly greater than the final desired linewidths and spacings.

11. The method according to claim 8, wherein the forming step comprises the steps of:
printing the conductor line pattern of the thick-film material on the principle surface of the substrate; and
firing the printed conductor line pattern to densify particles in the thick-film material and adhere the pattern to the substrate.

12. The method according to claim 8, wherein the masking step comprises to steps of:
covering the principle surface of the substrate with a layer of photoresist; and
patterning the layer of photoresist so that the selected portions of the underlying conductor line pattern are exposed.

13. The method according to claim 8, wherein the removing step is performed by etching the substrate.
